(19) United States
(12) Patent Application Publication
(10) Pub. No.: US 2010/0227460 A1
(43) Pub. Date: Sep. 9, 2010

(54) METHOD OF MANUFACTURING NOR FLASH MEMORY

(75) Inventors: Yider Wu, Chu-Pei City (TW); Yung-Chung Lee, Chu-Pei City (TW); Yi-Hsiu Chen, Chu-Pei City (TW)

Correspondence Address: SCHMEISER, OLSEN & WATTS, 22 CENTURY HILL DRIVE, SUITE 302, LATHAM, NY, 12110, US

(73) Assignee: EON SILICON SOLUTIONS INC., Chu-Pei City (TW)

(21) Appl. No.: 12/399,377

(22) Filed: Mar. 6, 2009

(51) Int. Cl. H01L 21/4763

(52) U.S. Cl. 438/586; 257/E21.496

(57) ABSTRACT

In a method of manufacturing a NOR flash memory, when the memory device dimensions are further reduced, the forming of spacers at two lateral sides of the gate structures is omitted, and a space between two gate structures can be directly filled up with a dielectric spacer or a shallow trench isolation (STI) layer. Therefore, it is possible to avoid the problem of increased difficulty in manufacturing memory device caused by forming spacers in an extremely small space between the gate structures. The method also enables omission of the self-alignment step needed to form the salicide layer. Therefore, the difficulty in self-alignment due to the extremely small space between the gate structures can also be avoided.

### FIELD OF THE INVENTION

The present invention relates to a method of manufacturing a flash memory, and more particularly to a method of manufacturing a NOR flash memory.

### BACKGROUND OF THE INVENTION

A flash memory is a non-volatile memory, which can maintain the information stored thereon even when no power is supplied thereto. This means an electronic device using the flash memory does not need to waste electric power for memorizing data. The flash memory is also rewritable, small in volume with high memory capacity, and easy to carry. Therefore, flash memories are particularly suitable for use with portable devices. Currently, NOR flash memories have been used not only on motherboards of computers for storing BIOS (basic input/output system) data, but also on mobile phones and hand-held devices for storing system data. In addition, the flash memory offers fast read access speed to satisfy the demands for quick boot speed of hand-held devices.

FIG. 1 is a schematic sectional view of a conventional memory, which includes a semiconductor substrate 100, two gate structures 102, a first and a second Co-silicide layer 104 separately formed atop the two gate structures 102, a third Co-silicide layer 106 formed atop the substrate 100 between the two gate structures 102, spacers 108 formed at two lateral sides of each of the gate structures, and a barrier plug 110. With the progress in semiconductor process technique, the process technique for memory devices also moves into the era of nanometer technology. For a nanometer-scale device structure, due to the tendency of reduced linewidth and the constantly reduced device dimensions, the linewidth for the memory devices becomes smaller and smaller to largely restrict other related structures in the memory devices. As can be seen from FIG. 1, when the device dimensions are constantly reduced, a distance between the two gate structures 102 becomes smaller and smaller, which results in difficulties in forming the spacers 108 at two lateral sides of the gate structures as well as the self-alignment of the first and second Co-silicide layers 104 with the gate structures 102.

It is therefore desirable to improve the flash memory devices to avoid structural and design restriction caused by the reduced dimensions of the memory devices, and to maintain memory device properties without increasing the complexity in designing the memory devices.

### SUMMARY OF THE INVENTION

A primary object of the present invention is to provide a method of manufacturing a NOR flash memory, so that, when the memory device dimensions are further reduced, the forming of spacers at two lateral sides of the gate structures can be omitted, and a space between two gate structures can be directly filled up using an oxide spacer or a shallow trench isolation (STI) oxide layer. Properties intended for a memory device manufactured through the method of the present invention can be maintained without the need of additional complicate manufacturing steps.

To achieve the above and other objects, the method of manufacturing a NOR flash memory according to a first embodiment of the present invention includes the steps of providing a semiconductor substrate; forming two gate structures on the semiconductor substrate; filling up a space between the two gate structures with a dielectric spacer; etching the oxide spacer, so that the remained dielectric spacer is flush with top surfaces of the gate structures; forming a salicide layer on the top surface of each of the gate structures; performing etching between the gate structures to form a contact hole; and forming a barrier plug in the contact hole.

According to a second embodiment of the present invention, the method of manufacturing a NOR flash memory includes the steps of providing a semiconductor substrate; forming two gate structures on the semiconductor substrate; filling up a space between the two gate structures with a shallow trench isolation (STI) layer; polishing the shallow trench isolation layer through a chemical mechanical polishing (CMP) process, so that the remained shallow trench isolation oxide layer is flush with top surfaces of the gate structures; forming a salicide layer on the top surface of each of the gate structures; performing etching between the gate structures to form a contact hole; and forming a barrier plug in the contact hole.

With the method of the present invention, it is able to avoid the problem of increased difficulty in manufacturing a memory device caused by forming spacers in an extremely small space between the gate structures. The present invention also enables omission of the self-alignment step needed to form the salicide layer. Therefore, the difficulty in self-alignment due to the extremely small space between the gate structures can also be avoided.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic sectional view showing the structure of a conventional memory device;

FIGS. 2 to 7 are sectional views of a NOR flash memory at different stages in a method of manufacturing a NOR memory according to the present invention;

FIG. 8 is a flowchart showing the steps of filling up a dielectric spacer between two gate structures on a NOR flash memory according to a first embodiment of the method of the present invention; and

FIG. 9 is a flowchart showing the steps of filling up a dielectric spacer between two gate structures on a NOR flash memory according to a second embodiment of the method of the present invention.

### DETAILED DESCRIPTION OF THE PREFERRED EMBODIMENTS

The present invention will now be described with some preferred embodiments thereof. For the purpose of easy to understand, elements that are the same in the illustrated preferred embodiments and the accompanying drawings are denoted by the same reference numerals.

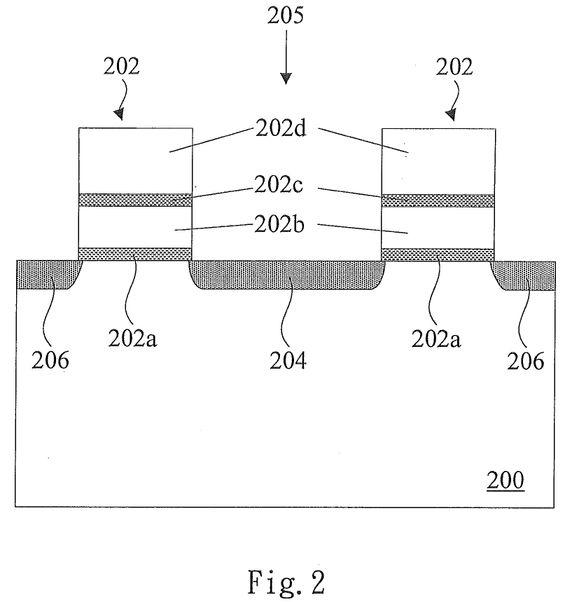

Please refer to FIGS. 2 to 7, which are sectional views showing a memory cell at different stages in a method of manufacturing a NOR flash memory according to a first embodiment of the present invention. In FIG. 2, a semiconductor substrate 200 is provided, and two gate structures 202 are formed on the substrate 200. Each of the two gate structures 202 includes a tunneling oxide layer 202a, a floating gate 202b, a dielectric layer 202c, and a control gate 202d. A channel 205, a lightly doped drain region 204, and two lightly doped source regions 206 are also formed in the semiconductor substrate 200. The material for the substrate 200 can be silicon, silicon-germanium (SiGe), silicon on insulator (SOI), silicon germanium on insulator (SGOI), or germanium on insulator (GOI). In the illustrated embodiments of the present invention, the substrate 200 is a silicon substrate. In the gate structure 202, the dielectric layer 202c is not necessarily a material with high dielectric constant as that usually used in the conventional gate structure. In the NOR memory manufacturing method of the present invention, materials with low dielectric constant, such as SiO₂, Si₃N₄, etc., can also be used to form the dielectric layer 202c. This enables a largely increased choice of dielectric materials.

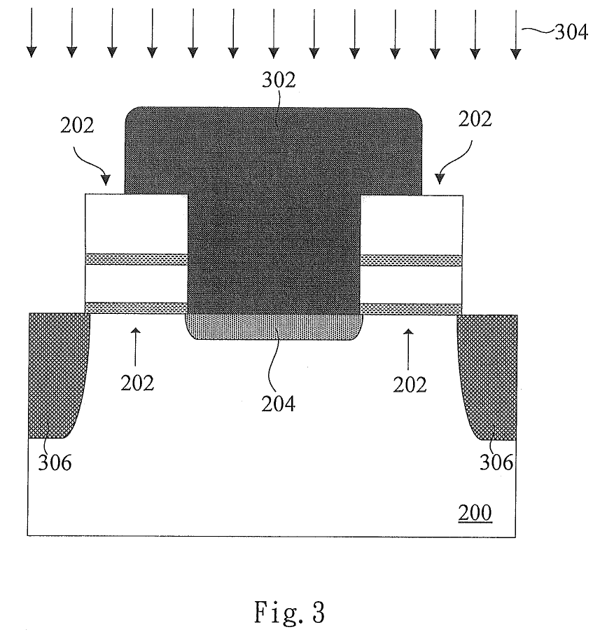

Please refer to FIG. 3. A mask 302 is formed on the semiconductor substrate 200, and the lightly doped drain region 204 is covered by the mask 302. The mask 302 can be a photoresist, an anti-reflection material, a hard mask, or any combination thereof. Then, an ion implantation process 304 for forming source is performed to implant a proper impurity into the semiconductor substrate 200 to form two first source regions 306.

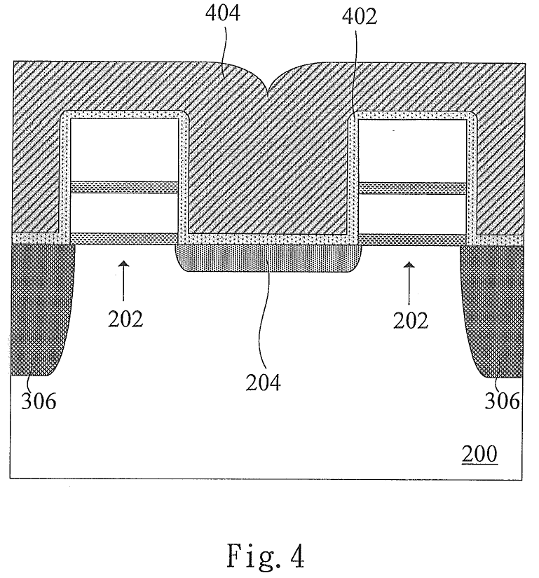

Then, as shown in FIG. 4, a contact etch stop layer (CESL) 402 is deposited on the semiconductor substrate 200. The CESL 402 can be SiN, silicon oxynitride, silicon oxide, etc. In the illustrated embodiments of the present invention, the CESL 402 is SiN. The CESL 402 has a deposition thickness ranged from 100 Å to 1500 Å. Thereafter, a dielectric spacer 404 is deposited through a deposition technique, such as chemical vapor deposition (CVD) process that uses NH₃ and SiH₄ as the source gases, rapid thermal chemical vapor deposition (RTCVD) process, or atomic layer deposition (ALD) process. As shown in FIG. 4, the dielectric spacer 404 not only fills up a space between the gate structures 202, but also covers the gate structures 202 and the CESL 402.

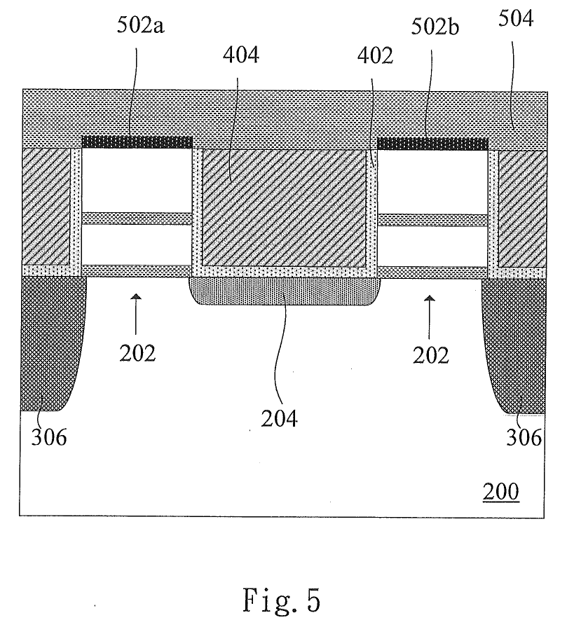

Please now refer to FIG. 5. The dielectric spacer 404 is etched through dry etching, wet etching, or combined dry and wet etching, so that the remained oxide spacer 404 is flush with top surfaces of the gate structures 202, and the CESL 402 on the top surfaces of the gate structures 202 is removed. Then, a metal silicide layer consisting of cobalt (Co), titanium (Ti), nickel (Ni), or molybdenum (Mo) is formed on the top of the remained oxide spacer 404, and a rapid thermal treatment process is performed, so that a salicide layer 502a, 502b is formed on the top surface of each of the gate structures 202 to reduce parasitic resistance and increase device driving force. Thereafter, an inter-layer dielectric (ILD) layer 504, such as SiO₂, is deposited on the salicide layer 502a, 502b and the dielectric spacer 404.

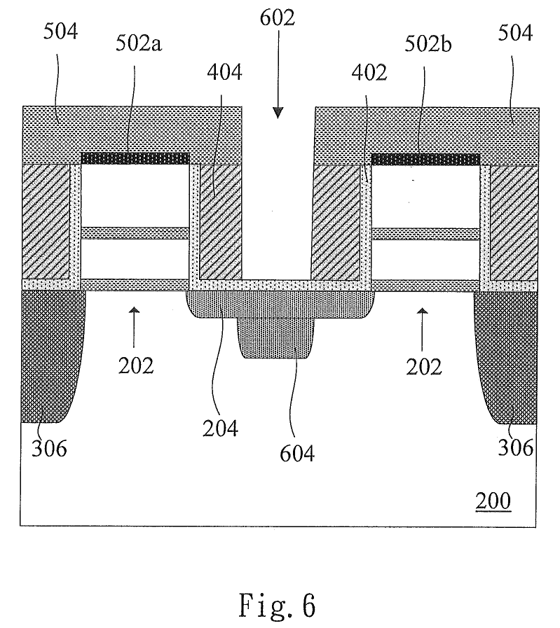

Referring to FIG. 6, through a photoresist and mask process, a contact hole 602 is formed between the gate structures 202 by anisotropic etching to extend from the inter-layer dielectric 504 to the CESL 402. Then, ion implantation for forming drain and rapid thermal treatment for activating intrinsic-device doping are performed to form a first drain region 604, which is located beneath the lightly doped drain region 204.

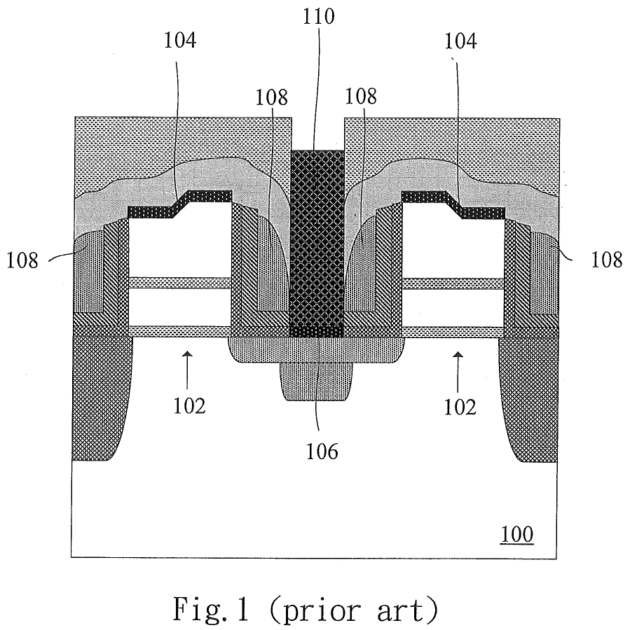

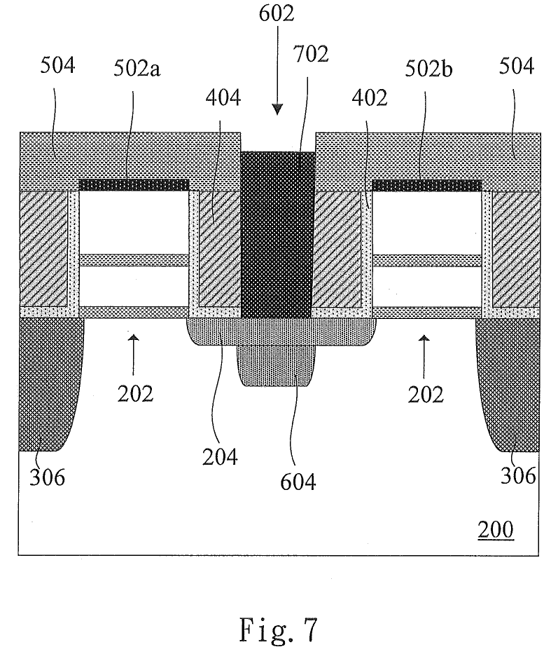

Referring to FIG. 7, after the above-described steps, a barrier plug 702 in the contact hole 602 is deposited through CVD process to form a NOR flash memory without the spacers 108 as being shown in FIG. 1.

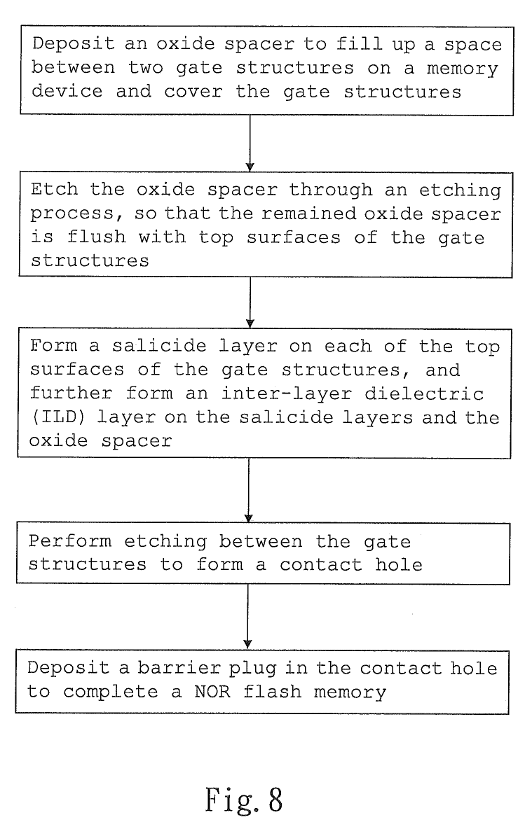

FIG. 8 is a flowchart showing the steps of filling up a dielectric spacer between two gate structures on a NOR flash memory according to a first embodiment of the method of the present invention. First, a dielectric spacer 404 is deposited to fill up the space between two gate structures 202 and cover the gate structures 202. Then, etch the dielectric spacer 404 through an etching process, so that the remained dielectric spacer 404 is flush with top surfaces of the two gate structures 202. Thereafter, form a salicide layer 502a, 502b on each of the top surfaces of the two gate structures 202, and further form an inter-layer dielectric (ILD) layer 504 on the salicide layers 502a, 502b and the dielectric spacer 404. Then, perform etching between the two gate structures 202 to form a contact hole 602. Finally, deposit a barrier plug 702 in the contact hole 602 to complete the NOR flash memory.

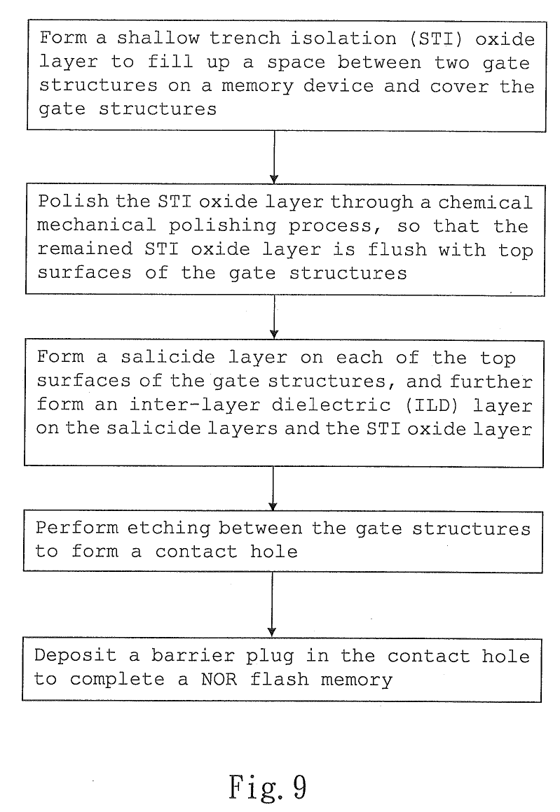

In a second embodiment of the present invention, the dielectric spacer is replaced by a shallow trench isolation (STI) layer. FIG. 9 is a flowchart showing the steps of filling up a dielectric spacer between two gate structures on a NOR flash memory according to the second embodiment of the method of the present invention. First, a shallow trench isolation (STI) layer is formed to fill up the space between two gate structures 202 and cover the gate structures 202. Then, polish the STI layer through a chemical mechanical polishing (CMP) process, so that the remained STI layer is flush with top surfaces of the two gate structures 202. Thereafter, form a salicide layer 502a, 502b on each of the top surfaces of the two gate structures 202, and further form an inter-layer dielectric (ILD) layer 504 on the salicide layers 502a, 502b and the STI layer. Then, perform etching between the two gate structures 202 to form a contact hole 602. Finally, deposit a barrier plug 702 in the contact hole 602 to complete the NOR flash memory.

The present invention has been described with some preferred embodiments thereof and it is understood that the illustrated preferred embodiments are used only to describe the present invention and are not intended to limit the scope of the present invention. It is also understood many changes and modifications in the described embodiments can be carried out without departing from the scope and the spirit of the invention that is intended to be limited only by the appended claims.

What is claimed is:

1. A method of manufacturing a NOR flash memory, comprising the steps of:
providing a semiconductor substrate;
forming two gate structures on the semiconductor substrate;
filling up a space between the two gate structures with a dielectric spacer;
etching the dielectric spacer, so that the remained oxide spacer is flush with top surfaces of the gate structures;
forming a salicide layer on each of the top surfaces of the gate structures;
performing etching between the gate structures to form a contact hole; and
forming a barrier plug in the contact hole.

2. A method of manufacturing a NOR flash memory, comprising the steps of:
providing a semiconductor substrate;
forming two gate structures on the semiconductor substrate;
filling up a space between the two gate structures with a shallow trench isolation layer;
polishing the shallow trench isolation oxide layer, so that the remained shallow trench isolation layer is flush with top surfaces of the gate structures;
forming a salicide layer on each of the top surfaces of the gate structures;
performing etching between the gate structures to form a contact hole; and
forming a barrier plug in the contact hole.

3. The method of manufacturing a NOR flash memory as claimed in claim 2, wherein the shallow trench isolation oxide layer is polished through a chemical mechanical polishing (CMP) process.
